(19) United States
(12) Patent Application Publication
(10) Pub. No.: US 2005/0161783 A1
(43) Pub. Date: Jul. 28, 2005

(54) Method for manufacturing circuit board, circuit board, and electronic equipment

(76) Inventor: Nobuaki Hashimoto, Suwa-shi (JP)

Correspondence Address: HARNESS, DICKEY & PIERCE, P.L.C., P.O. BOX 828, BLOOMFIELD HILLS, MI, 48303, US

(21) Appl. No.: 11/002,425

(22) Filed: Dec. 2, 2004

(30) Foreign Application Priority Data
Dec. 24, 2003 (JP) 2003-426720

(51) Int. Cl. H01L 23/02; H01R 12/16

(52) U.S. Cl. 257/678

(57) ABSTRACT

A method for manufacturing a slim, highly reliable circuit board, wherein connection between electrodes of a chip component and a wiring pattern on the board can be readily and stably established, a circuit board, and electronic equipment including the circuit board are provided. The method includes the steps of disposing the chip component in a through hole provided in an open board in accordance with the height of the chip component; and forming a wiring pattern on the open board and establishing connections between the wiring pattern and the electrodes on the chip component. A support material is attached to the open board.

### BACKGROUND OF THE INVENTION

1. Field of the Invention

The present invention relates to a method for manufacturing a circuit board, the circuit board, and electronic equipment. In particular, the present invention relates to a method for manufacturing a circuit board provided with a chip component, in which semiconductor devices and electronic circuits are constructed, the circuit board, and electronic equipment.

2. Description of the Related Art

The chip on board (COB) mounting is previously known, in which, for example, a chip component including semiconductor devices, electronic circuits, and the like is arranged and mounted on a surface provided by a wiring board (hereafter referred to as on a board) made of polyethylene terephthalate (PET) or the like. In this COB mounting, for example, the step of connecting a wiring pattern formed on a board by a silk screen printing method and the like to electrodes provided on a chip component is performed and, thereby, a circuit board is produced, as disclosed in Japanese Unexamined Patent Application Publication No. 2003-46026 (page 3) and the like. Examples of methods for establishing this connection include one type of screen printing method in which the electrodes and the wiring pattern are joined with a liquid containing electrically conductive metal particles, the liquid is removed by evaporation or the like, and only the metal particles are fixed and solidified by sintering or the like so as to establish connection. The formation of the wiring pattern on the wiring board and the establishment of connection to the electrodes can be performed by this method in a single step as well.

Here, in order to minimize the area occupied by the chip component disposed on the wiring board, electrodes serving as external terminals of circuits and the like included in the chip component may be formed on a surface provided by the chip component (hereafter referred to as on a chip component). In this case, usually, a height difference larger than or equal to the height of the chip component is created between the electrodes on the chip component placed on the wiring board and the surface to be provided with the wiring pattern. In the above-described printing method, since the liquid tends to become discontinuous when the height difference becomes larger than a certain extent, the establishment of connection and the formation of the wiring pattern become impossible. A height difference created between the electrode and the chip component surface does not cause any particular problem, but a height difference between the chip component and the wiring board constitutes a problem here.

Consequently, the connections between the electrodes and the wiring pattern are realized by performing the processing, e.g., sliming of the chip component itself or potting processing to form an inclined surface around the chip component and, thereby, to absorb the height difference between the electrodes and the surface to be provided with the wiring pattern.

However, in this case, an additional processing, the potting processing, is required. When the potting processing is performed, the chip component, wiring board, and the like are further exposed to heat. When a slim chip component is produced, a further improvement in precision is required correspondingly. Consequently, it is difficult to readily and stably connect the electrodes on the chip component to the wiring pattern on the board as well as to produce the chip component.

### SUMMARY OF THE INVENTION

Accordingly, it is an object of the present invention to provide a method for manufacturing a slim, highly reliable circuit board wherein connections between electrodes of a chip component and a wiring pattern on the board can be readily and stably established, the circuit board, and electronic equipment including the circuit board.

A method for manufacturing a circuit board, according to the present invention, includes the steps of disposing a chip component in a concave portion or a through hole provided in a wiring board in accordance with the height of the chip component; and forming a wiring pattern on the wiring board and establishing connections between the wiring pattern and electrodes on the chip component with wirings containing electrically conductive particles.

A method for manufacturing a circuit board, according to the present invention, includes the steps of disposing a chip component in a concave portion or a through hole provided in a wiring board in accordance with the height of the chip component; and establishing connection between electrodes on the chip component and a wiring pattern formed on the wiring board in advance with wirings containing electrically conductive particles.

In the method for manufacturing a circuit board, according to the present invention, the concave portion or the through hole may be provided to have a width and a length in accordance with the width and the length of the chip component in addition to the height.

In the method for manufacturing a circuit board, according to the present invention, the chip component may be a bare chip.

In the method for manufacturing a circuit board, according to the present invention, the electrodes included in the bare chip may be covered with electrically conductive metals.

In the method for manufacturing a circuit board, according to the present invention, a resin may be present between the chip component and the wall surface of the concave portion or the through hole when the chip component is disposed in the concave portion or the through hole.

In the method for manufacturing a circuit board, according to the present invention, the resin present between the chip component and the wall surface of the concave portion or the through hole may be a resin to join the chip component to the concave portion or the through hole.

In the method for manufacturing a circuit board, according to the present invention, the wirings may be formed from both surfaces of the chip component disposed in the concave portion or the through hole.

In the method for manufacturing a circuit board, according to the present invention, the wiring pattern may be formed or the connection may be established by discharging a liquid containing an electrically conductive substance from a droplet discharge device.

In the method for manufacturing a circuit board, according to the present invention, the wiring pattern may be formed or the connection may be established by printing a material containing an electrically conductive substance.

The method for manufacturing a circuit board, according to the present invention, may further include the step of subjecting the entire or a part of the circuit board to lamination processing after the wiring pattern is formed or the connection is established.

In the method for manufacturing a circuit board, according to the present invention, the concave portion or the through hole of the wiring board may be formed in advance during the production of the wiring board.

In the method for manufacturing a circuit board, according to the present invention, the concave portion or the through hole of the wiring board may be formed by an etching method after the wiring board is produced.

A circuit board according to the present invention is provided with a chip component including electrodes; a wiring board including a concave portion or a through hole in accordance with the height of the chip component while a chip component is disposed in the concave portion or the through hole; and a wiring containing electrically conductive particles, the wiring being disposed on the wiring board simultaneously with being extended and electrically connected to the electrodes of the chip component.

The circuit board according to the present invention may include a wiring pattern disposed on the wiring board in advance, wherein the wirings are disposed and connected to the wiring pattern on the wiring board in a single step.

In the circuit board according to the present invention, the wirings may be disposed on both surfaces of the wiring board.

In the circuit board according to the present invention, the chip component may be a bare chip.

In the circuit board according to the present invention, the electrodes included in the bare chip may be covered with electrically conductive metals.

Electronic equipment according to the present invention includes any one of the above-described circuit boards.

According to the present invention, the chip component is disposed in the concave portion or the through hole provided in the wiring board in accordance with the height of the chip component, the wiring pattern is formed on the wiring board, and the connections are established between the wiring pattern formed in advance and the electrodes on the chip component, or the wiring pattern is formed and connected to the electrodes in a single step. Consequently, the height difference created between the electrodes on the chip component and the wiring board surface due to the height of the chip component can be reduced, and the configuration can be made flat. Furthermore, since the wiring pattern is formed and connected to the electrodes by the use of the printing method, e.g., an ink-jet (droplet ejection) system, no additional processing is required in the production of the chip component or the production of the circuit board. Therefore, the process can be simplified, and the circuit board can be produced stably in a short time. The wiring and the connection by the use of the ink-jet (droplet ejection) system is effective on a reduction of the cost, a reduction of the production time, and the environment, e.g., resource conservation. As a matter of course, since the height difference is small, the wiring pattern can be formed and the connections to the electrodes on the chip component can be established by the use of common methods, e.g., screen printing, as well, and a plurality of circuit boards can be formed at the same time, the production time can be reduced. It is more preferable that the concave portion or the through hole is provided to further have the width and the length in accordance with a width and a length of the chip component and, thereby, the gap is reduced.

In particular, when the chip component is a bare chip, the thickness is small compared with that of a package component and the chip component can be readily used. When the electrodes on the bare chip are formed from or covered with an electrically conductive metal, the electrical conductivity can be improved. Furthermore, the chip component can be readily fixed to the concave portion or the through hole by being joined with a resin. At that time, the gap created between the chip component and the concave portion or the through hole can be filled in by adjusting the amount of the resin.

When the wiring board has an opening, since the electrodes can be disposed on both surfaces of the chip component and the wiring pattern can be formed and connected to the electrodes on the chip component, the board can be used effectively, and a plurality of wiring patterns can be formed, for example. The circuit board can be protected by being subjected to the lamination processing. When the wiring board includes a through hole, one of surfaces to be provided with chip component can also be constructed by blocking one end of the hole.

With respect to the wiring board, by forming the concave portion or the through hole in advance during the production of the board, a separate formation step becomes unnecessary, and it is convenient when mass production is performed, for example. Conversely, an already-available wiring board can be used by forming the concave portion or the through hole by the use of an etching method or the like after the board is produced.

Since the thus produced circuit board has a stable two-dimensional structure, the mechanical strength is also increased, and the reliability of the circuit board can be improved. Furthermore, the entire circuit board can be made low profile.

### BRIEF DESCRIPTION OF THE DRAWINGS

FIG. 1 is a sectional view of a circuit board according to a first embodiment of the present invention.

FIG. 2 is a diagram showing an example of the procedure of a method for manufacturing a circuit board.

FIG. 3 is a diagram showing an example of the configuration of a droplet discharge device.

FIG. 4 is a diagram of a circuit board viewed from the top surface side.

FIG. 5 is a sectional view of a circuit board according to a second embodiment.

FIGS. 6A to 6C are diagrams showing electronic equipment including the circuit board produced according to the present invention.

### DESCRIPTION OF THE PREFERRED EMBODIMENTS

### First Embodiment

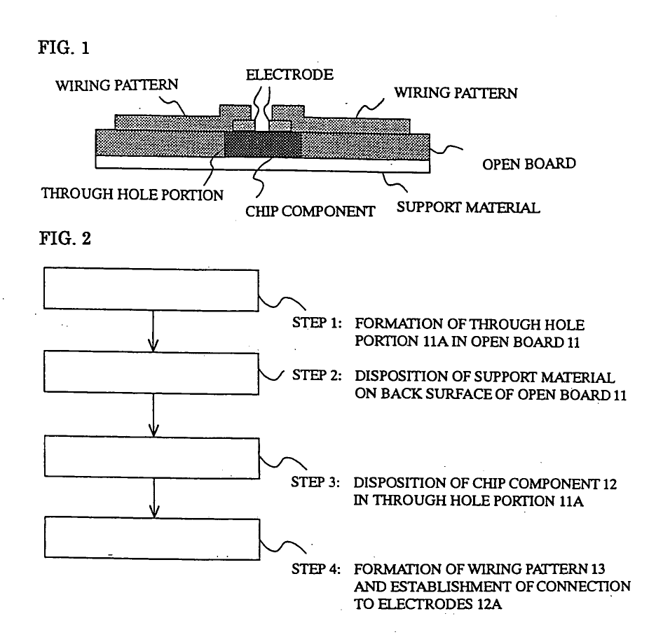

FIG. 1 is a sectional view of a circuit board according to the first embodiment of the present invention. In FIG. 1, an open board 11 is a wiring board provided with a through hole portion 11A to dispose a chip component 12 in the inside. The open board 11 is composed of an insulating material, e.g., polyethylene terephthalate (PET), bakelite, or an epoxy resin. However, the material is not limited to them as long as the material has the heat resistance in processing and the insulating property, and is suitable for forming a wiring pattern 13. In the present embodiment, the height (corresponds to the depth or the thickness of the open board 11 as well) of the through hole portion 11A is in accordance with the height of the chip component 12. This is to connect electrodes 12A and the wiring pattern 13 with a liquid containing electrically conductive metal particles without occurrence of break. Ideally, there is no height difference between the height of the through hole portion 11A and the height of the chip component 12 or the two are substantially equal to each other. However, it is difficult to require that there is no height difference between all of various open boards 11 and chip components 12. Therefore, “in accordance with” refers to adjust the height of the through hole portion 11A and the height of the chip component 12 in order that the connection is readily established during the formation of wiring described later without occurrence of break, short circuit, or the like (when the electrodes 12A are disposed at the end portion on the chip component, the height thereof may be taken into consideration). For example, in order to bring about the electrically connected state without any inconvenience of occurrence of break, short circuit, or the like, the occurrence of break can be prevented in spite of the height difference between the electrode 12A and the chip component 12 (on the order of 20 μm in many cases), as a matter of course, and even when the height difference is increased up to, e.g., the height of the chip component 12 (about 1 to a few millimeter) under some conditions, although depending on the viscosity and the like of the liquid used in a step described later. When the height of the through hole portion 11A is larger than the height of the chip component 12, the height can be readily adjusted by the resin and the like disposed under the chip component 12 and, therefore, it is preferable that the height of the through hole portion 11A is not brought into the condition of being too smaller than the height of the chip component 12. On the other hand, the length and the width of the through hole portion 11A are not specifically limited. However, the chip component 12 must be disposed in the through hole, as a matter of course, and it is desirable that the length and the width of the opening of the through hole portion 11A are made to become in accordance with the length and the width of the chip component 12 in order to minimize the gap created between the side wall of the through hole and the chip component 12 to establish the connection effectively. However, preferably, the gap is filled in with the resin in order to improve the formability of the wiring described later. The inner side wall of the through hole portion 11A is not necessarily perpendicular to a surface to be provided with the wiring pattern 13.

The chip component 12 is a component in which electronic circuits and the like are constructed in a chip form, for example. In the present embodiment, a bare chip of an integrated circuit (IC), that is, a semiconductor device, is used as the chip component 12. However, the chip component 12 is not specifically limited to the bare chip, and a chip component in which electronic circuits and the like are packaged may be used. The chip component 12 may be composed of a single electric or electronic device in place of a circuit formed from integrated semiconductor devices. The electrodes 12A are disposed on this chip component 12. The electrodes 12A are covered with electrically conductive metallic materials in order to improve electrical characteristics. In many cases, the covering is performed by means of plating, sputtering, evaporation, printing, or the like, although the method is not limited. Preferably, the plating is performed by an electrolysis method or an electroless plating method. In general, the type of metal is copper, nickel, gold, silver, platinum, tin, or solder. Nickel, titanium, tungsten, platinum, chromium, or the like is used as a barrier layer. Combinations of at least two types of these metals, alloys thereof, and the like may be used. Known technologies for forming bumps and known technologies for forming barrier layers can be used therefor. Preferably, at least a covering surface is made of a noble metal having oxidation resistance and good electrical connectivity to the wiring. The electrode 12A itself may be formed from such a metal.

The wiring pattern 13 is disposed on the open board 11 in order to be electrically connected between the chip component 12 and other devices and circuits in the open board 11 or to electrically connect the above-described devices and the circuits to devices, circuits, and the like in the outside of the open board 11 through terminals (not shown in the drawing). An electrically conductive substrate, e.g., copper, silver, gold, other metals, or alloys, is used for the wiring pattern 13. In general, fine powders or nanoparticles of these metals are mixed with organic materials so as to become ink, paste, or the like, and the electrical conductivity is exhibited by means of heating or the like. In the present embodiment, the wiring pattern 13 is formed and connected to the electrodes 12A in a single step. However, the wiring pattern may be formed separately by generally known etching of copper foil. A support material 14 is to support the disposition of the chip component 12. In the present embodiment, the support material 14 is formed by, for example, lamination processing of a base film. For example, an insulating material, e.g., PET, is used for the support material 14 as in the open board 11. The support material 14 also performs the function of protecting the inside of the circuit board simultaneously. An adhesive may be laminated on the support material.

A generally known mounting system of an electronic component is a method in which a chip component is disposed on a wiring board. On the other hand, in the present embodiment, the open board 11 provided with the through hole portion 11A is used, the chip component 12 is disposed in the through hole portion 11A, and thereby, the height difference created between the electrode 12A on the chip component 12 and a surface provided by the open board 11 is reduced or eliminated. Consequently, the formation of the wiring pattern 13 and the wiring on the open board 11 including the electrodes 12A can be accomplished in a single step, wherein the wiring includes, for example, the establishment of connections between the electrodes 12A and the wiring pattern 13.

FIG. 2 is a diagram showing an example of the procedure of a method for manufacturing a circuit board. The method for manufacturing a circuit board will be described with reference to FIG. 2. The through hole portion 11A is formed in the open board 11 (Step 1). Examples of methods for forming the through hole portion 11A include a method in which the through hole portion 11A is formed by the use of a mold or the like simultaneously with the production of the open board 11 and a method in which the open board 11 provided with no through hole portion 11A is produced and, thereafter, the through hole portion 11A is formed by the use of etching, for example. Here, the through hole portion 11A may be formed by either method. In the description of the present embodiment, the through hole portion 11A is assumed to be formed in advance. However, with respect to the timing of the formation, particularly in the case where the through hole portion 11A is formed after the open board 11 is produced, the through hole portion 11A may be formed after the wiring pattern 13 is formed as long as the through hole portion 11A is formed before the chip component 12 is mounted therein.

The support material 14 is disposed on the surface (hereafter referred to as back surface) opposite to the surface to be provided with the wiring pattern 13 of the open board 11 (Step 2). The “lamination processing” refers to a processing method in which a surface of a film, provided with an adhesive (resin) is aligned with the back surface of the open board 11 and, thereafter, heating and pressure-joining by application of a pressure with a roller or the like are performed. The lamination processing is a processing method accompanied with the heating and, therefore, is performed preferably before the chip component 12 is disposed.

After the support material 14 is attached, the chip component 12 is disposed in the through hole portion 11A (Step 3). At this time, one opening of the through hole portion 11A is covered with the support material 14, and serves as a bottom for disposing the chip component. Here, it is desirable that the chip component 12 is adhered with, for example, a pasty, liquid, or sheet-shaped adhesive or resin (hereafter referred to as adhesive). This step may be performed as in a known die attach step. In the step, more preferably, the amount of the adhesive is adjusted in order that the adhesive extended off the bottom of the chip component 12 fills in the gap created between the chip component 12 and the through hole portion 11A and, thereby, the surface provided by the open board 11 and the surface provided by the chip component 12 are joined with as flat a surface as possible. Alternatively, this gap may be filled in with an adhesive by means of dispensing, ink jet (droplet discharge), printing, or the like in a separate step.

After the chip component 12 is disposed in the through hole portion 11A, the wiring pattern 13 is formed and connected to the electrodes 12A (Step 4). In the present embodiment, these formation and connection are performed in a single step. A droplet discharge device is used for performing the formation and the like. The droplet discharge device refers to a device, e.g., a so-called ink-jet printer, which discharges a liquid by an ink-jet (droplet discharge) system. Although the printer discharges ink, the droplet discharge device in the present embodiment discharges a liquid containing an electrically conductive substance, e.g., metal particles. In many cases, electrically conductive substances, e.g., copper, silver, gold, other metals, and alloys, are used as the metal fine particles. In general, it is preferable that these metals are ink in which fine powders or nanoparticles are mixed with organic materials. When the formation of the wiring pattern 13 and the establishment of connection are performed by the use of this system, in contrast to a generally known system used for production of boards, the etching method is unnecessary for formation of the wiring pattern 13. That is, the electrically conductive substance is not applied all over the surface, nor is the electrically conductive substance removed. A required amount of the liquid containing an electrically conductive substance can be supplied to a required portion. Therefore, the efficiency is high, the cost performance is excellent, and waste is minimized, so that the environmental friendliness and the like are increased correspondingly.

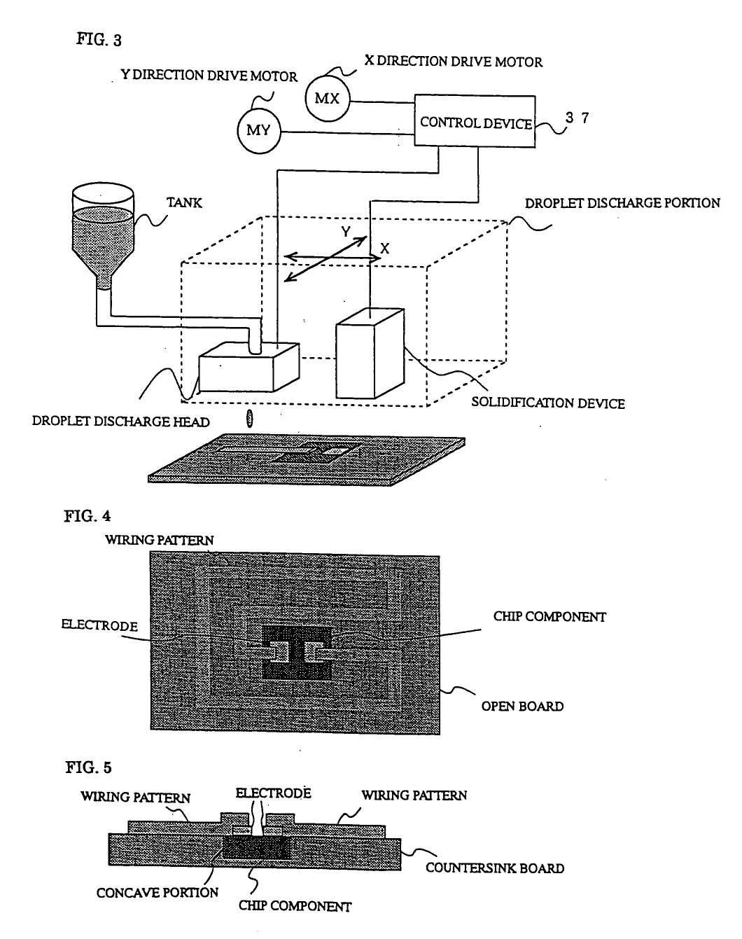

FIG. 3 is a diagram showing an example of the configuration of a droplet discharge device. In FIG. 3, a droplet discharge portion 31 is composed of a droplet discharge head 32 to discharge a liquid by a droplet discharge system and a solidification device 33. The droplet discharge head 32 is a head to pressurize the liquid with a piezoelectric element, an electrostatic force, or a gas produced by heating the liquid and to discharge the liquid as droplets. The solidification device 33 is a device to stably and promptly fix and solidify the electrically conductive substance by a physical or chemical treatment. The liquid containing the electrically conductive substance is fed from a tank 34 through a flow path, and becomes the wiring pattern 13 and the connection wiring.

An X direction drive motor 35 and a Y direction drive motor 36 constitute a part of a drive mechanism, and are stepping motors, for example. When X axis direction driving signals and Y axis direction driving signals are supplied from a control device 37, the drive motors 35 and 36, respectively, move the droplet discharge portion 31 together with other devices constituting the drive mechanism (not shown in the drawing) in accordance with the driving signals.

The control device 37 transmits signals for controlling the droplet discharge to the droplet discharge head 32 and, thereby, control (control to form the wiring pattern and the like) the droplet discharge, while the signals are produced based on the data of the board wiring prepared by, for example, a computer aided design (CAD) soft. The control device 37 transmits signals for controlling the action of the solidification device 33 as well. Furthermore, the control device 37 transmits driving signals for controlling the movement of the droplet discharge portion 31 in the X axis direction and in the Y axis direction to the X direction drive motor 35 and the Y direction drive motor 36. The configuration of the droplet discharge device shown in FIG. 3 is one example. In the present embodiment, for example, the droplet discharge device 31 may be fixed and a pedestal (not shown in the drawing) to hold the open board 11 may be moved. Other various methods may be adopted.

FIG. 4 is a diagram of the circuit board viewed from the top surface side. After the wiring pattern 13 is formed and the connection between the wiring pattern 13 and the electrodes 12A are established, for example, terminals required for the connection to the outside are formed, if necessary, although not shown in the drawing (this may be performed simultaneously with the formation of the wiring pattern 13 and the like). The surface provided with the wiring pattern may be covered with a film or the like by lamination processing or the like in order to protect the chip component 12, wiring pattern 13, and the like. Alternatively, a seal or other materials may be disposed. A sealing resin, a metal cap, or the like may be attached. A coating of the sealing resin may be applied by an ink-jet (droplet discharge) method.

As described above, according to the first embodiment, the chip component 12 is disposed in the through hole portion 11A of the open board 11 and, thereby, the height difference between the electrodes 12A on the chip component 12 and the surface provided by the open board 11 can be minimized and the resulting surface becomes flat. In this manner, the formation of the wiring pattern 13 and the establishment of connection between the wiring pattern 13 and the electrodes 12A can be realized by the wiring formation method through the use of the droplet discharge device. Consequently, the process can be simplified, and the circuit board can be produced stably in a short time. Since the chip component 12 and the open board 11 do not overlap each other, a very low profile circuit board can be produced even when the chip component 12 is not very severely made slim. Therefore, with respect to the chip component 12 as well as the circuit board, an increase in yield and a reduction in cost can be achieved. Furthermore, if a slim chip component is adopted, the effect of slimming becomes further noticeable. Since the formation of the wiring pattern 13 and the establishment of connection between the wiring pattern 13 and the electrodes 12A can be performed in a single step, the production time of the circuit board can be reduced. Conversely, since the wiring pattern 13 can be formed in advance in the production of the open board 11 (before the chip component 12 is disposed), the flexibility in the production process can be increased.

Since the wiring pattern 13 can be formed and connected to the electrodes 12A by discharging the liquid containing the electrically conductive substance to only a desired position with the droplet discharge device, good effects are exerted on a reduction of the cost, a reduction of the production time, and the environment, e.g., resource conservation. Any etching bath and other devices are unnecessary, and the circuit board of the present embodiment can be produced as long as the droplet discharge device is disposed. Therefore, space saving of the production devices can also be achieved. In addition, the thickness of the wiring can be changed locally, and a portion at which break or short circuit tends to occur can be repaired. Consequently, in the wiring step as well, the height difference and the gap created between the chip component 12 and the open board 11 can be filled in.

In particular, when the chip component 12 is a bare chip, a further low-profile circuit board can be produced compared with that in the case of a package component. The support material is formed on the entire or a part of the open board 11 by the lamination processing. Consequently, one opening of the through hole portion 11A can be blocked, and the open board 11, the chip component 12, the wiring pattern 13, and the like can be protected. Since the circuit board produced by this method has a stable two-dimensional structure, the mechanical strength can also be increased, and the reliability of the circuit board can be improved. Furthermore, the entire circuit board is made low-profile.

With respect to the open board 11, a through hole serving as the through hole portion 11A is formed in advance with a mold or the like in the production of the board and, thereby, the step of forming the through hole becomes unnecessary. This is advantageous in mass production, for example. Conversely, the through hole serving as the through hole portion 11A is formed by means of etching or the like after the board is produced and, thereby, an already-available wiring board can be used as the open board 11.

### Second Embodiment

FIG. 5 is a sectional view of a circuit board according to the second embodiment. In FIG. 5, elements indicated by the same reference numerals as in FIG. 1 perform the functions similar to those in FIG. 1, and further explanations thereof will not be provided. In FIG. 5, reference numeral 21 denotes a countersink board. The countersink board refers to a board provided with a concave portion 21A. That is, the open board 11 is provided with the through hole portion 11A, whereas the countersink board 21 is provided with the concave portion 21A in contrast to the open board 11. Here, the side wall surface of the concave portion 21A is not necessarily perpendicular to the surface to be provided with the wiring pattern 13. In many cases, the countersink of the board is formed by a mold or processing with a router.

The chip component 12 is disposed in the concave portion 21A provided in the countersink board 21. In this case, the concave portion 21A is not penetrated, in contrast to the through hole portion 11A. Consequently, when the chip component 12 is disposed, the support material 14 serving as a bottom is unnecessary, in contrast to that in the first embodiment. When the height of the chip component 12 to be disposed is known in advance, the countersink board 21 can be formed to include the concave portion having the depth in accordance with the height of the chip component 12, or the concave portion 21A can be formed in the wiring board by means of etching or the like, so that the countersink board 21 can be prepared. It is convenient that the concave portion 21A is thus formed to have the depth (height) in accordance with the component to be used. Although detailed explanations will not be provided here to avoid overlaps, the components and the manufacturing method explained in the method according to the first embodiment can be applied without modification except that the countersink board 21 is used.

As described above, according to the second embodiment, the chip component 12 is disposed in the concave portion 21A provided in the countersink board 21 and, thereby, the height difference created between the electrodes 12A on the chip component 12 and the surface provided by the countersink board 21 can be minimized and the resulting surface can be made flat. Therefore, the wiring pattern 13 can be formed and the connection between the wiring pattern 13 and the electrodes 12A can be established by, for example, the wiring formation method through the use of the droplet discharge device. Since the formation of the wiring pattern and the establishment of the connection between the wiring pattern 13 and the electrodes 12A can be performed in a single step, the production time of the circuit board can be reduced. Conversely, since the wiring pattern 13 can be formed in advance in the production of the countersink board 21 (before the chip component 12 is disposed), the flexibility in the production process can be increased. The other effects are similar to those in the first embodiment.

### Third Embodiment

In the above-described embodiments, the wiring of the wiring pattern 13 and the establishment of connection to the electrodes 12A are performed through the use of the droplet discharge device, although the present invention is not limited to this. These may be performed in a printing step. The formation of the wiring pattern 13 and the establishment of connection by the printing may be performed through a system in which electrically conductive ink, paste, or the like is printed by a screen printing system. At this time, the wiring to be used may be prepared by a known method for manufacturing a board, and only the joining may be performed by the use of the above-described ink-jet (droplet discharge) system in which electrically conductive droplets are discharged. By the use of this method, a plurality of boards can be subjected to a treatment of forming the wiring and the like at a time.

### Fourth Embodiment

In the above-described embodiments, the electrodes 12A are disposed on the surface of the chip component 12. However, electrodes may also be disposed on the so-called back surface. By disposing the electrodes on the back surface as well, connection to the wiring pattern formed on the back surface can be established through the use of the through hole portion 11A and, thereby, both surfaces can be provided with the wirings. Consequently, both surfaces of the open board 11 can be used effectively.

### Fifth Embodiment

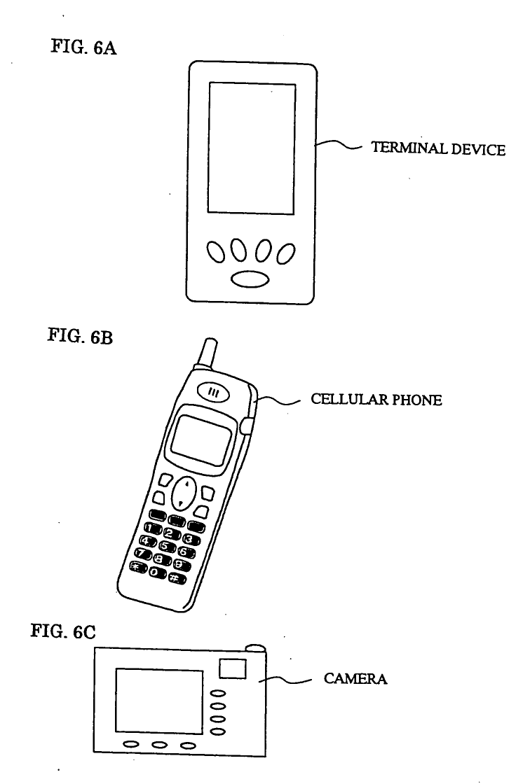

FIGS. 6A to 6C are diagrams showing electronic equipment including the circuit board produced according to the present invention. When the circuit boards produced in the above-described embodiments are used as memory, and the boards are used in a terminal device 41, a cellular phone 42, a camera 43, and other electronic equipment, it is expected that these can be made slimmer than ever. In particular, it is convenient that the circuit boards can be used in the equipment strongly required to be miniaturized and slimmed. The circuit boards can also be used in so-called IC cards, IC chips (tags), and the like. For example, the circuit boards can be used for purposes such as IC cards of either non-contact type or contact type. The circuit boards can be used as, for example, card type treatment devices and other various card type electronic equipment depending on purposes of chip components 12.

In every embodiment described above a plurality of chip components may be mounted and joined, or different types of component may be mounted together.

In every embodiment, other components mounted by known mounting systems (for example, reflow technology) and any mounting and joint system in the above-described embodiments may be combined.

1. A method for manufacturing a circuit board, the method comprising the steps of:
disposing a chip component in a concave portion or a through hole provided in a wiring board in accordance with the height of the chip component; and
forming a wiring pattern on the wiring board and establishing connections between the wiring pattern and electrodes on the chip component with wirings containing electrically conductive particles.

2. A method for manufacturing a circuit board, the method comprising the steps of:
disposing a chip component in a concave portion or a through hole provided in a wiring board in accordance with the height of the chip component; and
establishing connections between electrodes on the chip component and a wiring pattern formed on the wiring board in advance with wirings containing electrically conductive particles.

3. The method for manufacturing a circuit board, according to claim 2, wherein the concave portion or the through hole is provided to have a width and a length in accordance with the width and the length of the chip component in addition to the height.

4. The method for manufacturing a circuit board, according to claim 2, wherein the chip component is a bare chip.

5. The method for manufacturing a circuit board, according to claim 4, wherein the electrodes included in the bare chip are covered with electrically conductive metals.

6. The method for manufacturing a circuit board, according to claim 2, wherein a resin is present between the chip component and the wall surface of the concave portion or the through hole when the chip component is disposed in the concave portion or the through hole.

7. The method for manufacturing a circuit board, according to claim 6, wherein the resin present between the chip component and the wall surface of the concave portion or the through hole is a resin to join the chip component to the concave portion or the through hole.

8. The method for manufacturing a circuit board, according to claim 2, wherein the wirings are formed from both surfaces of the chip component disposed in the concave portion or the through hole.

9. The method for manufacturing a circuit board, according to claim 2, wherein the wiring pattern is formed or the connection is established by discharging a liquid containing an electrically conductive substance from a droplet discharge device.

10. The method for manufacturing a circuit board, according to claim 2, wherein the wiring pattern is formed or the connection is established by printing a material containing an electrically conductive substance.

11. The method for manufacturing a circuit board, according to claim 2, the method further comprising the step of subjecting the entire or a part of the circuit board to lamination processing.

12. The method for manufacturing a circuit board, according to claim 2, wherein the concave portion or the through hole of the wiring board is formed in advance during the production of the wiring board.

13. The method for manufacturing a circuit board, according to claim 2, wherein the concave portion or the through hole of the wiring board is formed by an etching method after the wiring board is produced.

14. A circuit board comprising:
a chip component including electrodes;
a wiring board including a concave portion or a through hole in accordance with the height of a chip component while the chip component is disposed in the concave portion or the through hole; and
a wiring containing electrically conductive particles, the wiring being disposed on the wiring board simultaneously with being extended and electrically connected to the electrodes of the chip component.

15. The circuit board according to claim 14 comprising a wiring pattern disposed on the wiring board in advance, wherein the wirings are disposed and connected to the wiring pattern on the wiring board in a single step.

16. The circuit board according to claim 15, wherein the wirings are disposed on both surfaces of the wiring board.

17. The circuit board according to claim 16, wherein the chip component is a bare chip.

18. The circuit board according to claim 17, wherein the electrodes included in the bare chip are covered with electrically conductive metals.

19. Electronic equipment comprising the circuit board according to claim 18.
